(19) United States
(12) Patent Application Publication
(10) Pub. No.: US 2021/0028338 A1
(43) Pub. Date: Jan. 28, 2021

(54) LED Phosphor Illumination Device

(71) Applicants: Mark W. Fuller, Sun Valley, CA (US); Garrett Young, Sun Valley, CA (US)

(72) Inventors: Mark W. Fuller, Sun Valley, CA (US); Garrett Young, Sun Valley, CA (US)

(21) Appl. No.: 16/938,853

(22) Filed: Jul. 24, 2020

Related U.S. Application Data
(60) Provisional application No. 62/878,251, filed on Jul. 24, 2019.

(51) Int. Cl. H01L 33/60; H01L 33/50

(52) U.S. Cl. CPC H01L 33/60; H01L 33/325; H01L 33/507; H01L 33/505

(57) ABSTRACT

A device that emits white light is disclosed. The device may include one or more LEDs within an elliptical cavity. The device may also include one or more phosphor elements positioned within the cavity in locations that correspond to the first and second focal points of the ellipse. The cavity may recirculate the light from the LEDs while transmitting the light altered by the phosphor elements.

### CROSS-REFERENCE TO RELATED APPLICATION

This application claims the benefit of U.S. Provisional Application No. 62/878,251, filed Jul. 24, 2019, the contents of which are incorporated herein by reference.

### COPYRIGHT STATEMENT

This patent document contains material subject to copyright protection. The copyright owner has no objection to the reproduction of this patent document or any related materials in the files of the United States Patent and Trademark Office, but otherwise reserves all copyrights whatsoever.

### FIELD OF THE INVENTION

This invention relates to illumination devices, including illumination devices involving LEDs and phosphor.

### BACKGROUND OF THE INVENTION

Light emitting diodes (LEDs) have become a dominate source of lighting for many applications. However, LEDs do not directly produce white light, and as such, must be modified in order to do so.

One method of producing white light using LEDs involves mixing red, blue and green LEDs to produce a spectral power distribution that appears white to the human eye. However, this typically results in poor color rendering (CRI) and poor efficacy.

Another method involves using phosphor materials to convert colored light emitted from LEDs to a light that appears white. However, many of these applications may have lower efficiencies due to losses in the systems.

Accordingly, there is a need for an illumination device that converts light emitted from LEDs to white light with higher efficiencies and efficacy.

### SUMMARY OF THE INVENTION

The present invention is specified in the claims as well as in the below description. Preferred embodiments are particularly specified in the dependent claims and the description of various embodiments.

In an aspect of the current invention a lighting device may include a phosphor material or assembly used to convert colored light to white light. For example, white light may be emitted as a combination of light from a light source of a certain color that is incident on the phosphor, and light of another color emitted from the phosphor. The phosphor assembly may be located remotely from the light source and may comprise phosphor rods.

In another aspect of the invention a lighting device may include a base with walls that form a cavity shaped as an ellipse. One or more phosphor rods may be positioned in the cavity. Light, such as LED light, may be emitted into the cavity and may reflect off the elliptical walls and pass through a phosphor rod. The wavelengths of the reflected and other light may combine to form white light. The white light may then be emitted through the walls of the cavity.

### BRIEF DESCRIPTION OF THE DRAWINGS

Various other objects, features and attendant advantages of the present invention will become fully appreciated as the same becomes better understood when considered in conjunction with the accompanying drawings, in which like reference characters designate the same or similar parts throughout the several views, and wherein:

FIGS. 1-3 show aspects of an illumination device according to exemplary embodiments hereof;

FIGS. 4-5 show aspects of an ellipse according to exemplary embodiments hereof;

FIG. 6 shows aspects of a coating material according to exemplary embodiments hereof; and

FIG. 7 shows aspects of an optical component according to exemplary embodiments hereof.

### DETAILED DESCRIPTION OF THE PREFERRED EMBODIMENTS

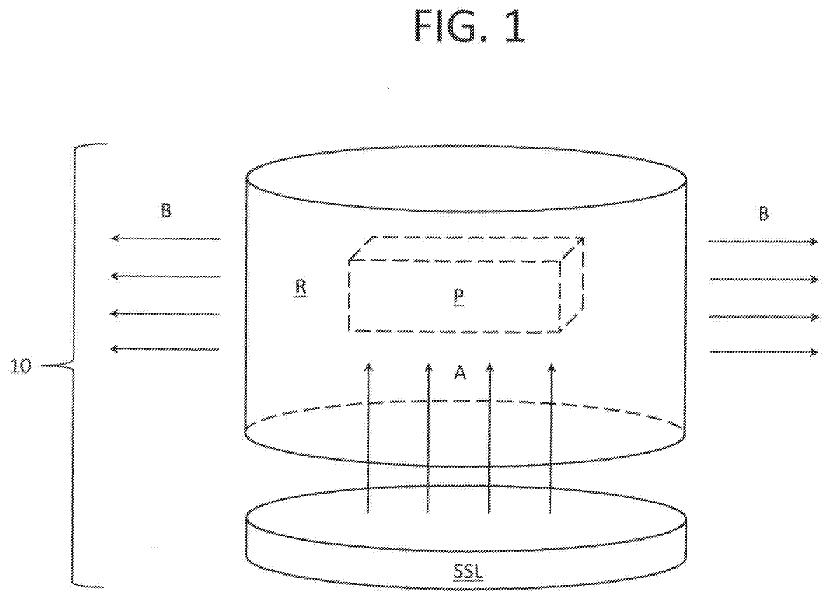

A device according to exemplary embodiments of the current invention is described with reference to FIGS. 1-7.

In general, as shown in FIG. 1, the device 10 may utilize phosphor P configured within a reflection cavity R to convert light A from a solid state lighting source SSL into a smooth white light output emission B.

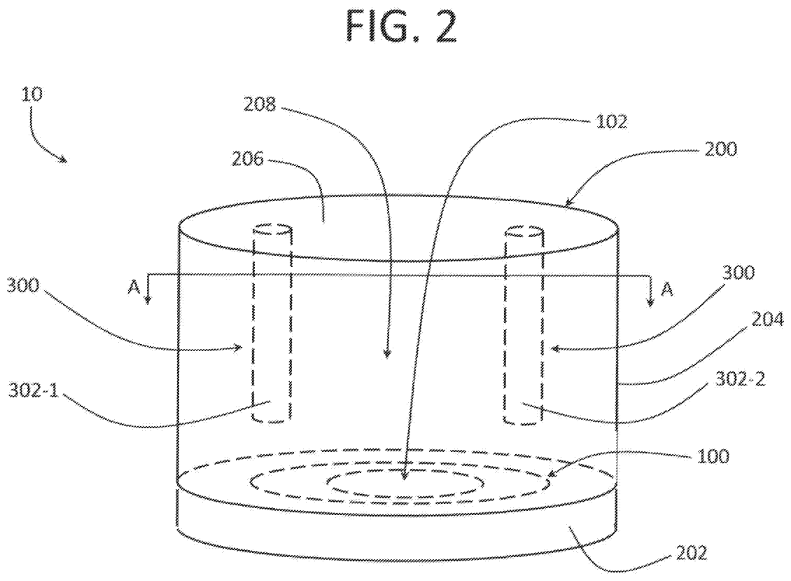

As shown in FIG. 2, in one exemplary embodiment hereof the device 10 may include an LED assembly 100, a housing assembly 200, and a phosphor assembly 300. The device 10 may also include other elements and components necessary to provide structures and to perform its functionalities as described in later sections or otherwise.

LED Assembly

In one exemplary embodiment hereof, the LED assembly 100 may include one or more light emitting diodes (LEDs) 102. The LEDs 102 may utilize GaN, InGaN, InN, AlN, other types of materials and/or their alloys and any combination thereof.

The LEDs 102 may be mounted within the housing assembly 200. The LEDs 102 may be surface mounted diodes (SMD), chip on board (COB), flip-chip (FC), other types of LEDs and/or any combination thereof. In one preferred implementation, the LEDs 102 may be mounted on a base structure within the housing assembly 200 as will be described in other sections.

In one exemplary embodiment, the LED assembly 100 may include LEDs 102 comprised of InGaN or other materials that may produce blue colored light with wavelengths λ of 450 nm-500 nm, violet colored light with wavelengths λ of 400 nm-450 nm, ultraviolet light with wavelengths λ of <400 nm (e.g., near ultraviolet light with wavelengths λ of 385 nm-400 nm) and/or other colors of light at other wavelengths. As will be described in other sections, the blue, violet, near ultraviolet and/or other colored light may then be affected by phosphors of different colors to form white light.

The LED assembly 100 preferably includes LEDs 102 that may be monochromatic, but this is not required.

The device 10 may include any number of any types or combinations of types of LEDs 102, and that the scope of the invention and of the embodiments of the device 10 is not limited in any way by the types of LEDs 102 that may be used. This may include, without limitation, any types of LEDs 102 utilizing any type(s) of solid state materials, LEDs 102 configured using any types of mounting and/or packaging techniques, LEDs 102 producing any emitted wavelengths, and/or any LEDs 102 with any other characteristics and any combination thereof.

### Housing Assembly

In one exemplary embodiment hereof as shown in FIG. 2, the housing assembly 200 may generally include a bottom 202 (also referred to as the base 202), side walls 204 and a top 206. In combination, the base 202, the side walls 204 and the top 206 may generally define the interior region 208 of the housing 200. As described in other sections, the interior region 208 may be a reflecting cavity 208 and/or a mixing cavity 208.

The LED assembly 100 may be mounted to the base 202 and the base 202 may include a dielectric material that may support and electrically insulate the LEDs 102. The base 202 may also include a heat sink comprising a thermally conducting material (e.g., aluminum or other thermally conductive material(s)), that may effectively draw the heat away from the LEDs 102, keeping them at a preferred operating temperature. This may lengthen the lifespan of the LEDs 102 and ensure that the LEDs 102 emit the preferred color of light.

The base 202 may provide power to the LED assembly 100 (e.g., forward voltage(s) and forward current(s)) as required by the LEDs 102 to emit the desired light.

The LED assembly 100 may be configured with the base 202 such that the LEDs 102 may generally emit light upward and into the inner cavity 208 of the housing 200. In a preferred implementation, the LEDs 102 may emit light directly upward in a direction that may be perpendicular to the base 202 and vertically parallel to the side walls 204. However, the LEDs 102 may also be positioned to emit light in any other direction(s) or orientation(s) with respect to the base 202, the side walls 204 and the inner cavity 208. In addition, different LEDs 102 may be configured in different orientations and/or positions with respect to one another.

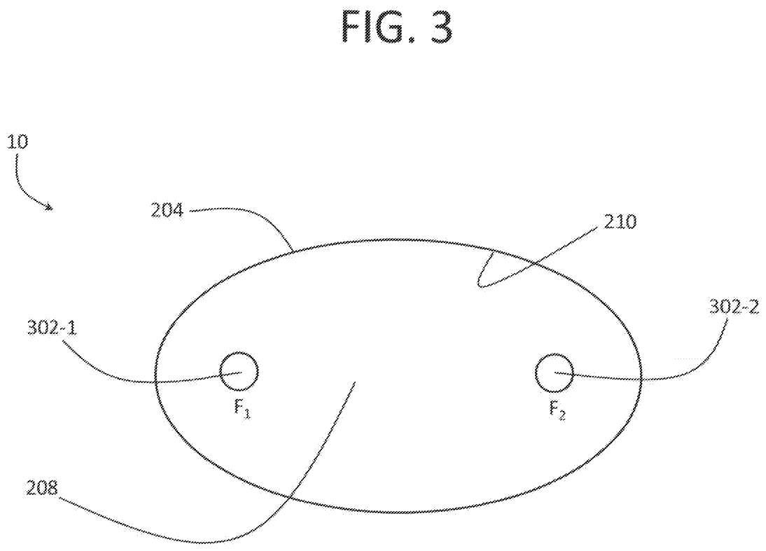

FIG. 3 is taken from the perspective of cut-lines A-A in FIG. 2, and shows the cross sectional shape of the inner region 208 formed by the side walls 204.

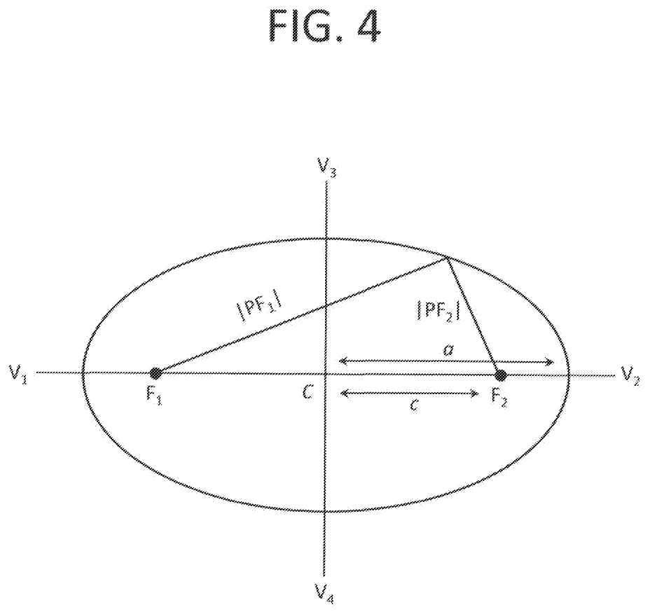

In an exemplary embodiment hereof, the cross sectional shape of the inner region 208 formed by the side walls 204 may define an ellipse. As is known in the art, an ellipse may be defined as a curve in a Euclidean plane surrounding two focal points such that the sum of the distances to the two focal points is constant for every point on the curve. As shown in FIG. 4, an ellipse may be defined using two focal points F₁ and F₂ and a distance (typically denoted as 2a). The ellipse defined by F₁, F₂ and 2a may be a set of points P such that the sum of the distances |PF₁|, |PF₂| may be constant and equal to 2a:

|PF₁|+|PF₂|=2a

The midpoint of the line segment joining the focal points F₁ and F₂ may be referred to as the center C of the ellipse. The line passing through the focal points F₁, F₂ may be referred to as the major axis, and the line perpendicular to the major axis and passing through the center C may be referred to as the minor axis. The major axis may include the vertices V₁ and V₂, which may each be a distance of a from the center C. The distance c from either focal point F₁, F₂ to the center C may be referred to as the focal distance or linear eccentricity. The eccentricity of the ellipse may be defined as the quotient c/a and may generally indicate how much the conic section deviates from being circular (note that the ellipse may be a circle when F₁=F₂).

In a preferred implementation, the elliptical cross sectional shape of the side walls 204 and the interior region 208 may include an ellipse with a width (defined by V₁-V₂) that may be twice the height (defined by V₃-V₄) of the ellipse. This may result in the cavity 208 having an eccentricity of approximately 0.85. However, other elliptical cross sections with other eccentricities may also be used.

Note that the case where F₁=F₂ (in which case the ellipse is a circle) is also contemplated in this specification. In addition, other variations of elliptically formed cross sections such as double-ellipses, multiple-ellipses, and other variations of elliptical forms may also be used in the current invention.

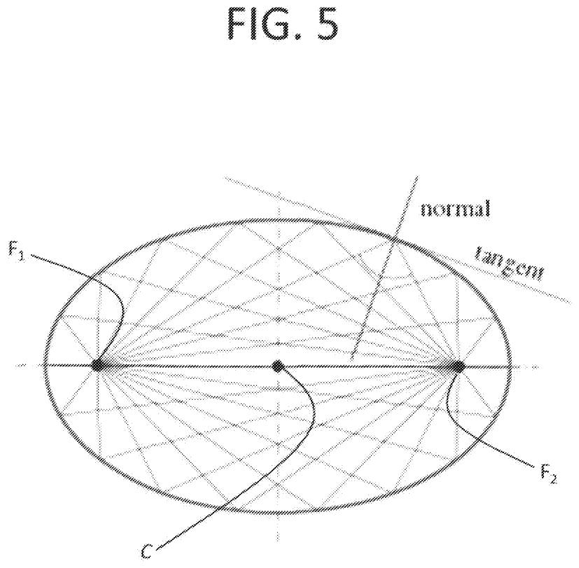

Regarding reflections within an ellipse, in Euclidean mathematics, when an incident ray meets the surface of a curve and is reflected, the angle of reflection between the reflected ray and the tangent of the curve at the incident point will equal the incident angle between the incident ray and the tangent of the curve at the incident point. Applying this to the inside of an ellipse as shown in FIG. 5, a ray that leaves one of the focal points (F₁ or F₂) and meets a point on the inside of the ellipse will reflect off the tangent of the ellipse at that point and pass through the other focal point (F₂ or F₁ respectively). This will be described in further detail in other sections.

In an exemplary embodiment hereof, the side walls 204 may be formed of a material (e.g., a transparent material such as optical-grade glass, Polycarbonate or other types of materials) that may allow light to pass through the walls 204 without significant loss, refraction and/or distortion. The inner surface 210 of the side walls 204 may include a thin film coating with transmission and reflection properties that may reflect certain frequencies of light while allowing other frequencies of light to pass through the coating. The thin film coating may be applied to either and/or both sides of the side walls 204 or otherwise be incorporated into the side walls 204 using any suitable methods or configurations.

In one preferred implementation, the thin film coating may reflect the output frequency(s) of the LEDs 102 while allowing other frequencies of light to pass through the thin film and the side walls 204. In this way, light emitted by the LEDs 102 may experience total internal reflection and remain within the inner region 208 of the housing 200 while other frequencies of light (e.g., light down-converted by the phosphor assembly 300 as described in other sections) may pass through the side walls 204 and be emitted from the device 10.

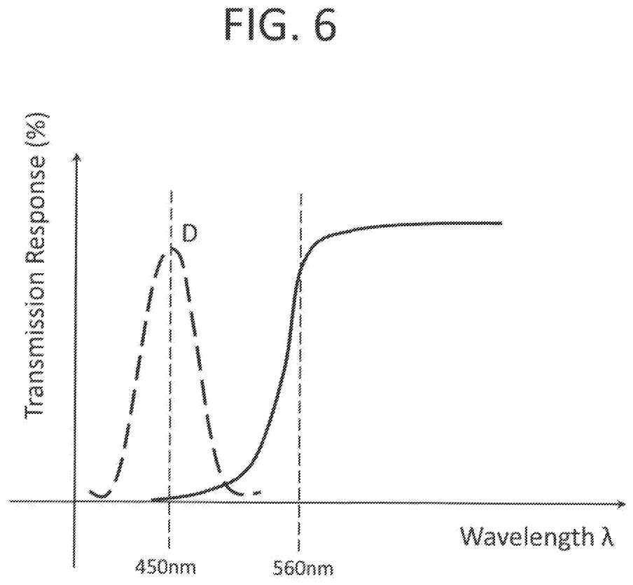

An example transmission response of an example thin film coating for this application is depicted in FIG. 6 for the case of InGaN LEDs 102 producing blue light (450 nm≤λ≤500 nm). As shown, the LEDs 102 may emit blue light D at wavelengths λ of approximately 450 nm. The thin film may include a longwave pass coating in the visible spectrum (or any other type of suitable coating) that may reject (e.g., preferably reflect vs. absorb) the 450 nm wavelength λ while allowing wavelengths λ greater than 560 nm (e.g., yellow light emitted by a phosphor element) to pass through the film. It may be preferable that the wavelengths λ that may transmit through the coating do so with minimal loss, attenuation, refraction or distortion. This example is meant for demonstration purposes, and other LEDs 102 emitting other wavelengths λ may be used with other thin film coatings that may reflect and transmit other desired wavelengths A, and the scope of the current invention or of the embodiments of the device 10 are not limited in any way by the frequencies of the LED light and/or the transmission/reflection properties of the coating.

In a preferred implementation, the side walls 204 may extend generally linearly from the base 202 to the top 206. In another preferred implementation, the side walls 204 may be at least approximately perpendicular to the base 202 and the top 206.

However, it is also contemplated in this specification that the side walls 204 may include curvatures and/or other non-linear elements that may reflect the light within the chamber 200 at different angles. For example, the side walls 204 may include curved sections, bowed sections, elliptical sections, parabolic sections, notches, steps, angled sections or other types of non-linear sections. In these cases, the side walls 204 may not necessarily be perpendicular to the bottom 202 and/or the top 206.

In a preferred implementation, the base 202 and/or the top 206 may be generally flat. However, it is also contemplated that the base 202 and/or the top 206 include non-flat elements such as curved sections, bowed sections, elliptical sections, parabolic sections, notches, steps, angled sections and other types of non-flat sections.

This may require phosphors of different forms and dimensions to be used with different configurations of the base 202 and/or the top 206.

In any event, it is preferred that the overall cross sectional shape of the side walls 204 and of the inner cavity 208 include a substantially constant shaped ellipse from the base 202 to the top 206 as shown in FIGS. 2 and 3.

In a preferred implementation, the base 202 may include a size and shape (e.g., elliptical) that may generally correspond with the cross-sectional shape of the side walls 204 shown in FIG. 2. In this way, the outer edges of the base 202 and the bottom edges of the side walls 204 may be flush with one another.

In another preferred implementation, the base 202 may extend outward beyond the side walls 204 and be of any shape and size. The portion of the base 202 that may extend beyond the side walls 204 may allow for more surface area of the base to be exposed to the outside environment such that the heat drawn from the LED assembly 100 by the base 202 may be thereby dissipated.

It may be preferable that the housing assembly 200 include contact terminals, sockets, adapters and/or other electrical connection elements that may allow the device 10 to be plugged into or otherwise configured with an external power source. For example, the housing 200 may include screw sockets such as medium (E26 socket), intermediate (E17 socket), candelabra (E12 socket), mini candelabra (E11 socket), miniature (E10 socket), 2-pin terminals, twist-lock connectors or other types of electrical connectors.

### Phosphor Assembly

In an exemplary embodiment hereof, the phosphor assembly 300 may be generally configured within the housing assembly 200 (e.g., within the reflection cavity 208). In this way, light emitted by the LED assembly 100 (e.g., blue light at wavelengths λ of 450 nm-500 nm) may enter the reflection cavity 208, strike the phosphor assembly 300 and be converted into white light. Because the phosphor assembly 300 may be configured separate from the LED assembly 200, the configuration may be referred to as a remote phosphor configuration.

Referring to FIG. 2, in an exemplary embodiment hereof, the phosphor assembly 300 may include one or more (preferably two) phosphor rods 302-1, 302-2, 302-3, . . . 302-n (individually or collectively 302). The phosphor rods 302 may comprise transparent or reflective materials that may be coated with one or more phosphor materials. The phosphor may also be in powder or particle form and may be suspended in resin, epoxy or silicon that may be used to form the rods 302 and/or otherwise be configured with the rods 302. In general, the phosphor material may be configured with the rods 302 using any suitable technique(s). In one preferred implementation, the phosphor rods 302 may be transparent and may include preformed polycarbonate rods (or other materials such as optical-grade glass or other suitable transparent materials) that may be coated with the phosphor material(s).

The phosphor material(s) may include phosphors such as cerium-doped yttrium aluminum garnet (Ce3+:YAG) phosphor that may illuminate white light when immersed in blue light. The white light may be formed as a combination of the blue light wavelengths and the yellow light wavelengths that may emit from the phosphor. Other phosphors or combinations of phosphors may also be used and it is understood that the scope of the current invention and of the embodiments of the device 10 is not limited in any way by the types of phosphors or combinations of phosphors utilized. For instance, depending on the color of the light emitted by the LEDs 102, several layers of phosphors of distinct colors may be used to broaden the emitted spectrum from the phosphors, effectively raising the color rendering index (CRI). In one example, near-UV LEDs may be used in combination with layers of red, blue and green colored phosphors.

It is preferred that the phosphor coating on the rods 302 be uniform, and as such, a conformal coating process or any other adequate coating process may be used. However, this may not be required.

In a preferred implementation, the phosphor rods 302 may be cylinders with circular or oval cross sections. It may be preferable that the diameters of the rods remain constant along the length of the rods but this may not be required. It may also be preferable that the rods 302-1, 302-2, . . . 302-n match in size and shape but this may not be required. Other shapes or forms of the rods may also be utilized such as rods with square, rectangular, triangular, hexagonal, other shaped cross sections or any combination thereof. Other forms such as cones, pyramids and other shapes or forms or any combination thereof may also be used. It is understood by a person of ordinary skill in the art that the rods 302 may be formed in any shape and size and that the scope of the device 10 is not limited in any way by the shape(s) and/or size(s) of the rods 302.

In a preferred implementation, the phosphor rods 302 may be vertically suspended within the housing 300 such that the rods 302 may be perpendicular to the elliptical cross-section of the reflection cavity 208. A first rod 302-1 may be configured at a position that may correspond to a first focal point F₁ of the cross-section of the elliptical cavity 208, and a second rod 302-2 may be configured at a position that may correspond to a second focal point F₂ of the cross-section of the elliptical cavity 208. It may be preferable that the rods 302 be suspended from the top 206 of the housing 200, but the rods 302 may be supported or otherwise configured with any combination of the base 202, the side walls 204, the top 206 or any combination thereof. The rods 302 may be secured directly to the top 206 and/or support structures may be used. In any event, it may be preferable that the rods 302 be suspended such that there may be minimal obstructions between the side walls 204 and the rods 302.

It may be preferable that the length of the rods 302 be such that the rods 302 may extend from the top 206 of the housing 200 to a position near the bottom 302 of the housing 200. In this way, the effect of losses at the end faces of the rods may be minimized. For example, the rods 302 may extend from the top 206 of the housing 200 downward 50%, 60%, 70%, 80%, 90% or other percentages of the overall height of the reflection cavity 208.

In addition, the entire length of one or more of the rods 302 may be configured with the phosphor (e.g., the phosphor coating), or alternatively, only a portion of the length of one or more of the rods 302 may include the phosphor. In one example, the rods 302 may include a phosphor coating on the lower 75% portion of the rods 302. In another example, the rods 302 may include a phosphor coating on the middle 50% portion of the rods 302. It is understood that the rods 302 may include phosphor on any portion of the rods 302, and that the portions that may include phosphor need not match from rod 302 to rod 302.

In this configuration, and given the discussion above regarding the internal reflection properties of an ellipse, light that may emit from the first phosphor rod 302-1 (e.g., at F₁) may generally reflect off the inner side wall 210 and pass through the second phosphor rod 302-2 (e.g., at F₂), and light that may emit from the second phosphor rod 302-2 (e.g., at F₂) may generally reflect off the inner side wall 210 and pass through the first phosphor rod 302-1 (e.g., at F₁). This will be described further in other sections.

The diameter of the rods 302 may be preferably chosen to maximize the intersection of the reflected light from the side walls 206 with the rods 302, and to account for any imperfections of the elliptical curvature of the side walls 206 (that may lead to slight imperfections in the directions of the reflected light). In one preferred implementation, the diameter of the rods 302 may be approximately equal to one-twelfth of the width of the elliptical cavity 208 (measured as V₁-V₂). However, it is understood that other diameters of the rods 302 may also be used, that the diameters of the rods 302 need not match, and that the scope of the current invention and of the embodiments of the device 10 are not limited in any way by the diameters of the rods 302.

The diameter of the phosphor rod(s) may be generally optimized for the specific phosphor compound and grain size distribution used. The optimization is between converting a substantial portion of the excitation light on the first pass, light loss through scattering and adsorption, and source size.

### In Use

In an exemplary embodiment hereof, the device 10 may emit white light. In one example, this may be achieved by the device 10 performing the following acts, without limitation:

1. The LED assembly 100 may emit a blue light upward into the reflection cavity 208.

2. The blue light emitted by the LED assembly 100 may reflect off the inner surfaces 210 of the elliptical side walls 204 due to the thin film coating's transmission/reflection response profile. As discussed above, the thin film may be chosen to reflect blue light.

3. As the light reflects, some of the blue light may pass through the first phosphor rod 302-1 located at first focal point F₁ of the elliptical cavity 208 formed by the side walls 204.

4. A portion of the blue light passing through the first phosphor rod 302-1 may undergo the Stokes effect and be converted to yellow light.

5. Another portion of the blue light may pass through the first phosphor rod 302-1 unaltered and may remain blue light.

6. The wavelengths of a portion of the yellow light and the wavelengths of a portion of the blue light passing through the first phosphor rod 302-1 may be combined to produce white light.

7. The white light may transmit through the thin film coating on the inner surface 210 of the side walls 204 and be emitted by the device 10. As discussed above, the thin film may be chosen to allow white light to pass through the coating.

8. A portion of the blue light that passes through the first phosphor rod 302-1 unaltered may be reflected off the thin film coating on the inner surface 210 of the side walls 204 and be directed into the second phosphor rod 302-2 located at second focal point F₂ of the elliptical cavity 208 formed by the side walls 204. This is due to the internal reflection properties of an ellipse as described in other sections.

9. A portion of the blue light passing through the second phosphor rod 302-2 may undergo the Stokes effect and be converted to yellow light.

10. Another portion of the blue light may pass through the second phosphor rod 302-2 unaltered and may remain blue light.

11. The wavelengths of a portion of the yellow light and the wavelengths of a portion of the blue light passing through the second phosphor rod 302-2 may be combined to produce white light.

12. The white light may transmit through the thin film coating on the inner surface 210 of the side walls 204 and be emitted by the device 10.

13. A portion of the blue light that passes through the second phosphor rod 302-2 unaltered may be reflected off the thin film coating on the inner surface 210 of the side walls 204 and be directed into the first phosphor rod 302-1 located at the first focal point F₁ of the elliptical cavity 208. This is due to the internal reflection properties of an ellipse as described in other sections.

14. The process of steps 1-13 may continue with blue light being recirculated within the reflection cavity 208 (reflected off the inner surface 210 of the side walls 206 and directed into the phosphor rods 302-1 and 302-1) and white light being transmitted through the side walls 204 and emitted by the device 10 as white light.

Note that once the device 10 is powered on and in operation, the steps 1-14 described above may occur simultaneously and in any order.

It is understood by a person of ordinary skill in the art, upon reading this specification, that the steps described above are meant for demonstration purposes and that other steps not disclosed may also be performed, not all of the steps described may be performed at all times, and any combination thereof.

It is also understood that while this specification may describe the LED assembly 100 as emitting blue light and the phosphor assembly 200 as down-converting the blue light to yellow light, the LED assembly 100 may transmit any color(s) of light (or any combinations of any color(s) of light) and the phosphor assembly 200 may convert the light emitted by the LED assembly 100 to any desired wavelength(s) (or any combinations of any desired wavelength(s)). The thin film coating on the inner surface 210 of the side walls 206 may then allow any desired wavelength(s) of light to pass through the side walls 206 to be emitted by the device 10, while reflecting any desired wavelengths to be recirculated within the mixing cavity 208.

It is therefore clear that the light emitted by the device 10 need not necessarily be white light, and that the various assemblies 100, 200, 300 of the device may be configured such that the device 10 may emit any desired color(s) or combination of color(s) of light.

In addition, while the above description(s) may describe light within the mixing chamber 208 as passing through the transparent phosphor rods 302, the phosphor rods 302 may also be reflective rods 302 that may instead reflect the light within the mixing cavity 208. It is also understood that the rods 302 may have both transmission and reflective characteristics such that a portion of the light may pass through the rods 302 and a portion of the light may reflect off the rods 302. In any event, it is clear that whether the light passes through the rods 302 or reflects off the rods 302, that the light may pass through the phosphor associated with the rods 302 (e.g., the phosphor coating(s)) such that a portion of the light may be down-converted. It is also clear that whether reflected off or transmitted through a first rod 302-1, 302-2, that the light may then be directed to a second rod 302-2, 302-1, respectively, given the elliptical cross section of the reflection cavity 208.

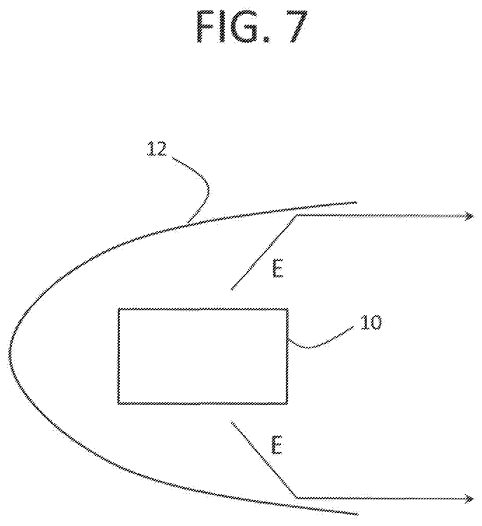

Note that other optical components and/or devices may be configured with the device 10. For example, as shown in FIG. 7, a reflector 12 may be configured with the device 10 in order to direct the emitted light E in a particular direction. Other types of components such as lenses, other components and any combination thereof may also be used with the device 10.

### Benefits of the Device

The benefits of the device 10 are multifold and include, without limitation:

First, the device 10 recirculates the photons (e.g., the blue photons as described in the examples above) emitted from the LED assembly 100 so that the photons are converted to a desired wavelength and emitted by the device 10. In this way, the (blue) photons are not lost as with other LED illumination devices, thereby providing a device 10 with improved efficacy and efficiency.

Second, because the remote phosphor rods 302 may be physically separated from the LED assembly 100, the heat associated with the blue-to-white wavelength conversion within the rods 302 may not affect the temperature of the LED assembly 100, allowing it to run cooler. This may allow for a lesser number of LEDs 102 that may be driven harder, and/or smaller heat sinks, thus saving money on material costs.

Third, the physical separation of the rods 302 and the LED assembly 100 may also protect the phosphor rods 302 from the heat produced by the LED assembly 100, such that the color, brightness and the duration of the afterglow of the phosphor material may be less affected by the heat.

Fourth, the remote phosphor rods 302 may act as diffusers (e.g., with Lambertian-like and/or Gaussian distributions), helping to achieve smooth white lighting while eliminating the need to add physical diffusers at a system level. This may further increase the optical efficiency and the system efficacy.

Fifth, the remote phosphor rods 302 provide a phosphor configuration with minimal increase in phosphor etendue over that of the source.

The result is a new white-light source with improved luminance, efficacy, efficiency and uniformity.

Those of ordinary skill in the art will appreciate and understand, upon reading this description, that embodiments hereof may provide different and/or other advantages, and that not all embodiments or implementations need have all advantages.

A person of ordinary skill in the art will understand, that any method described above or below and/or claimed and described as a sequence of steps is not restrictive in the sense of the order of steps.

Where a process is described herein, those of ordinary skill in the art will appreciate that the process may operate without any user intervention. In another embodiment, the process includes some human intervention (e.g., a step is performed by or with the assistance of a human).

As used herein, including in the claims, the phrase “at least some” means “one or more,” and includes the case of only one. Thus, e.g., the phrase “at least some ABCs” means “one or more ABCs”, and includes the case of only one ABC.

As used herein, including in the claims, term “at least one” should be understood as meaning “one or more”, and therefore includes both embodiments that include one or multiple components. Furthermore, dependent claims that refer to independent claims that describe features with “at least one” have the same meaning, both when the feature is referred to as “the” and “the at least one”.

As used in this description, the term “portion” means some or all. So, for example, “A portion of X” may include some of “X” or all of “X”. In the context of a conversation, the term “portion” means some or all of the conversation.

As used herein, including in the claims, the phrase “using” means “using at least,” and is not exclusive. Thus, e.g., the phrase “using X” means “using at least X.” Unless specifically stated by use of the word “only”, the phrase “using X” does not mean “using only X.”

As used herein, including in the claims, the phrase “based on” means “based in part on” or “based, at least in part, on,” and is not exclusive. Thus, e.g., the phrase “based on factor X” means “based in part on factor X” or “based, at least in part, on factor X.” Unless specifically stated by use of the word “only”, the phrase “based on X” does not mean “based only on X.”

In general, as used herein, including in the claims, unless the word “only” is specifically used in a phrase, it should not be read into that phrase.

As used herein, including in the claims, the phrase “distinct” means “at least partially distinct.” Unless specifically stated, distinct does not mean fully distinct. Thus, e.g., the phrase, “X is distinct from Y” means that “X is at least partially distinct from Y,” and does not mean that “X is fully distinct from Y.” Thus, as used herein, including in the claims, the phrase “X is distinct from Y” means that X differs from Y in at least some way.

It should be appreciated that the words “first,” “second,” and so on, in the description and claims, are used to distinguish or identify, and not to show a serial or numerical limitation. Similarly, letter labels (e.g., “(A)”, “(B)”, “(C)”, and so on, or “(a)”, “(b)”, and so on) and/or numbers (e.g., “(i)”, “(ii)”, and so on) are used to assist in readability and to help distinguish and/or identify, and are not intended to be otherwise limiting or to impose or imply any serial or numerical limitations or orderings. Similarly, words such as “particular,” “specific,” “certain,” and “given,” in the description and claims, if used, are to distinguish or identify, and are not intended to be otherwise limiting.

As used herein, including in the claims, the terms “multiple” and “plurality” mean “two or more,” and include the case of “two.” Thus, e.g., the phrase “multiple ABCs,” means “two or more ABCs,” and includes “two ABCs.” Similarly, e.g., the phrase “multiple PQRs,” means “two or more PQRs,” and includes “two PQRs.”

The present invention also covers the exact terms, features, values and ranges, etc. in case these terms, features, values and ranges etc. are used in conjunction with terms such as about, around, generally, substantially, essentially, at least etc. (i.e., “about 3” or “approximately 3” shall also cover exactly 3 or “substantially constant” shall also cover exactly constant).

As used herein, including in the claims, singular forms of terms are to be construed as also including the plural form and vice versa, unless the context indicates otherwise. Thus, it should be noted that as used herein, the singular forms “a,” “an,” and “the” include plural references unless the context clearly dictates otherwise.

Throughout the description and claims, the terms “comprise”, “including”, “having”, and “contain” and their variations should be understood as meaning “including but not limited to”, and are not intended to exclude other components unless specifically so stated.

It will be appreciated that variations to the embodiments of the invention can be made while still falling within the scope of the invention. Alternative features serving the same, equivalent or similar purpose can replace features disclosed in the specification, unless stated otherwise. Thus, unless stated otherwise, each feature disclosed represents one example of a generic series of equivalent or similar features.

The present invention also covers the exact terms, features, values and ranges, etc. in case these terms, features, values and ranges etc. are used in conjunction with terms such as about, around, generally, substantially, essentially, at least etc. (i.e., “about 3” shall also cover exactly 3 or “substantially constant” shall also cover exactly constant).

Use of exemplary language, such as “for instance”, “such as”, “for example” (“e.g.,”) and the like, is merely intended to better illustrate the invention and does not indicate a limitation on the scope of the invention unless specifically so claimed.

While the invention has been described in connection with what is presently considered to be the most practical and preferred embodiments, it is to be understood that the invention is not to be limited to the disclosed embodiment, but on the contrary, is intended to cover various modifications and equivalent arrangements included within the spirit and scope of the appended claims.

What is claimed is:

1. An illumination device comprising:
a cavity with side walls with reflection and transmission properties;
at least one light source emitting a first wavelength of light into the cavity; and
at least one phosphor element positioned within the cavity and emitting a second wavelength of light;
wherein the first wavelength of light is reflected off the side walls and the second wavelength of light is transmitted through the side walls.

2. The device of claim 1 wherein the second wavelength of light is produced by altering the first wavelength of light.

3. The device of claim 1 wherein the at least one light source includes at least one LED.

4. The device of claim 1 wherein the side walls define an ellipse.

5. The device of claim 4 wherein a first of the at least one phosphor element is positioned at a first focal point of the ellipse, and the second of at least one phosphor element is positioned at a second focal point of the ellipse.

6. The device of claim 5 wherein the first and second phosphor elements include rods positioned vertically within the cavity.

7. The device of claim 6 wherein the rods include at least one phosphor coating.

8. The device of claim 6 wherein the rods extend downward from the top of the cavity.

9. The device of claim 5 wherein the first wavelength of light is directed to the first phosphor element or the second phosphor element.

10. The device of claim 1 wherein the side walls include a thin film coating.

11. The device of claim 10 wherein the thin film coating includes a longwave pass coating in the visible spectrum.
